(19) United States
(12) Patent Application Publication
(10) Pub. No.: US 2025/0380575 A1
(43) Pub. Date: Dec. 11, 2025

(54) DISPLAY PANEL AND DEVICE WITH UNDER SCREEN CAMERA

(71) Applicant: HKC CORPORATION LIMITED, SHENZHEN (CN)

(72) Inventors: Qin LIANG, SHENZHEN (CN); Yangling TANG, SHENZHEN (CN); Zhisheng XIE, SHENZHEN (CN); Zhi YANG, SHENZHEN (CN); Pei XU, SHENZHEN (CN)

(21) Appl. No.: 19/224,182

(22) Filed: May 30, 2025

(30) Foreign Application Priority Data
Jun. 11, 2024 (CN) 202410749771.4

(51) Int. Cl. H10K 59/122; H10K 59/126; H10K 59/131; H10K 59/65; H10K 59/80; H10K 102/10

(52) U.S. Cl. CPC H10K 59/122; H10K 59/126; H10K 59/131; H10K 59/65; H10K 59/8051; H10K 59/873; H10K 2102/103

(57) ABSTRACT

A display panel and a device with an under screen camera are provided. The display panel includes pixel areas and a light-transmitting area. Each pixel area includes a pixel driving layer, a planarization layer defining connecting holes, a pixel defining layer, and a sub-pixel unit including a sub-pixel and an isolation structure. The connecting hole is located within an orthographic projection of the isolation structure on the planarization layer. Alternatively, when the planarization layer further extends to the light-transmitting area, the connecting holes are defined in the light-transmitting area; alternatively, a part of each connecting hole is defined in the corresponding pixel areas, another part of the connecting hole is defined in the light-transmitting area, and the part of the connecting hole defined in the corresponding pixel area is located within an orthographic projection of the isolation structure on the planarization layer.

### CROSS-REFERENCE TO RELATED APPLICATIONS

This application claims priority to Chinese Patent Application No. 202410749771.4, filed on Jun. 11, 2024 in the National Intellectual Property Administration of China, the contents of which are herein incorporated by reference in their entireties.

### TECHNICAL FIELD

Some embodiments of the present disclosure relate to the field of display technology, and in particular to a display panel and a device with an under screen camera.

### BACKGROUND

An organic light-emitting diode (OLED) display device is a device that realizes graphical display through utilizing a reversible color-changing phenomenon of an organic semiconductor material under current drive. The OLED display device offers advantages, such as ultra-lightweight, ultra-thin profile, high brightness, wide viewing angle, low voltage, low power consumption, fast response, high definition, shock resistance, flexibility, low cost, simple manufacturing process, low material usage, high luminous efficiency, and wide operating temperature range. Therefore, OLED display technology is considered the most promising next-generation display technology.

However, during a manufacturing process of an existing OLED display panel, it is required to define a via in a planarization layer, which tends to cause uneven deposition of an anode, thereby affecting the light-emitting performance of the display panel.

### SUMMARY OF THE DISCLOSURE

Some embodiments of the present disclosure may provide a display panel and a device with an under screen camera, in order to address a technical problem in the related art where unevenness of an anode affects a light-emitting performance of the display panel.

In order to address the technical problem above, a first technical solution provided by the present disclosure may provide a display panel configured in a device with an under screen camera. The display panel may have an under screen camera area. The under screen camera area may include a plurality of pixel areas and a light-transmitting area disposed at a side of the plurality of pixel areas. The display panel may include a plurality of pixel structures. The plurality of pixel structures may be disposed in the plurality of pixel areas. Each of the plurality of pixel structures may be disposed in a corresponding one of the plurality of pixel areas. Each of the plurality of pixel areas may include a pixel driving layer, a planarization layer, a pixel defining layer, and a sub-pixel unit that are sequentially stacked on one another. The planarization layer may define a plurality of connecting holes. The pixel defining layer may define a plurality of pixel openings. Each sub-pixel unit may include a sub-pixel and an isolation structure. The sub-pixel may be disposed in a corresponding one of the plurality of pixel openings. An anode of the sub-pixel may be electrically connected to the pixel driving layer through a corresponding one of the plurality of connecting holes. The isolation structure may protrude from the pixel defining layer and surround the corresponding one of the plurality of pixel openings. The isolation structure may be electrically connected to a cathode of the sub-pixel surrounded by the isolation structure. The sub-pixel may be substantially circular or elliptical in shape. Each of the plurality of connecting holes may be located within an orthographic projection of the isolation structure on the planarization layer. Alternatively, the planarization layer may further extend to the light-transmitting area and the plurality of connecting holes may be defined in the light-transmitting area. Alternatively, the planarization layer may further extend to the light-transmitting area, a part of each of the plurality of connecting holes may be defined in a corresponding one of the plurality of pixel areas, another part of each of the plurality of connecting holes may be defined in the light-transmitting area, and the part of each of the plurality of connecting holes defined in the plurality of pixel areas may be located within an orthographic projection of the isolation structure on the planarization layer.

In order to address the technical problem above, a second technical solution provided by the present disclosure may provide a device with an under screen camera. The device with the under screen camera may include a display panel and a camera module. The display panel may have a display side and a non-display side that are disposed on opposite to each other. The camera module may be disposed on the non-display side of the display panel and arranged corresponding to the under screen camera area. The display panel may have an under screen camera area. The under screen camera area may include a plurality of pixel areas and a light-transmitting area disposed at a side of the plurality of pixel areas. The display panel may include a plurality of pixel structures. The plurality of pixel structures may be disposed in the plurality of pixel areas. Each of the plurality of pixel structures may be disposed in a corresponding one of the plurality of pixel areas. Each of the plurality of pixel areas may include a pixel driving layer, a planarization layer, a pixel defining layer, and a sub-pixel unit that are sequentially stacked on one another. The planarization layer may define a plurality of connecting holes. The pixel defining layer may define a plurality of pixel openings. Each sub-pixel unit may include a sub-pixel and an isolation structure. The sub-pixel may be disposed in a corresponding one of the plurality of pixel openings. An anode of the sub-pixel may be electrically connected to the pixel driving layer through a corresponding one of the plurality of connecting holes. The isolation structure may protrude from the pixel defining layer and surround the corresponding one of the plurality of pixel openings. The isolation structure may be electrically connected to a cathode of the sub-pixel surrounded by the isolation structure. Each of the plurality of connecting holes may be located within an orthographic projection of the isolation structure on the planarization layer. Alternatively, the planarization layer may further extend to the light-transmitting area and the plurality of connecting holes may be defined in the light-transmitting area. Alternatively, the planarization layer may further extend to the light-transmitting area, a part of each of the plurality of connecting holes may be defined in a corresponding one of the plurality of pixel areas, another part of each of the plurality of connecting holes may be defined in the light-transmitting area, and the part of each of the plurality of connecting holes defined in the plurality of pixel areas may be located within an orthographic projection of the isolation structure on the planarization layer.

In order to address the technical problem above, a third technical solution provided by the present disclosure may provide a display panel configured in a device with an under screen camera. The display panel may have an under screen camera area. The under screen camera area may include a plurality of pixel areas and a light-transmitting area disposed at a side of the plurality of pixel areas. The display panel may include a plurality of pixel structures. The plurality of pixel structures may be disposed in the plurality of pixel areas. Each of the plurality of pixel structures may be disposed in a corresponding one of the plurality of pixel areas. Each of the plurality of pixel areas may include a pixel driving layer, a planarization layer, a pixel defining layer, and a sub-pixel unit that are sequentially stacked on one another. The planarization layer may define a plurality of connecting holes. The pixel defining layer may define a plurality of pixel openings. Each sub-pixel unit may include a sub-pixel and an isolation structure. The sub-pixel may be disposed in a corresponding one of the plurality of pixel openings. An anode of the sub-pixel may be electrically connected to the pixel driving layer through a corresponding one of the plurality of connecting holes. The isolation structure may protrude from the pixel defining layer and surround the corresponding one of the plurality of pixel openings. The isolation structure may be electrically connected to a cathode of the sub-pixel surrounded by the isolation structure. A part of the anode disposed in the corresponding one of the plurality of connecting holes may surround and define a conductive groove. An orthographic projection of the conductive groove on the pixel driving layer may be non-overlapped with an orthographic projection of the corresponding one of the plurality of pixel openings on the pixel driving layer.

### BRIEF DESCRIPTION OF THE DRAWINGS

In order to more clearly illustrate the technical solutions in some embodiments of the present disclosure, a brief introduction will be given below to the drawings required in the description of the embodiments. It is evident that the drawings described below are merely some embodiments of the present disclosure, and those skills in the art may obtain other drawings based on the following drawings without creative work.

FIG. 1 is a schematic structural view of a first embodiment of a display panel according to the present disclosure.

FIG. 2 is an enlarged schematic structural view of a pixel structure according to some embodiments of the present disclosure.

FIG. 3 is a schematic structural sectional view at E-E in FIG. 2.

FIG. 4 is a schematic structural sectional view at F-F in FIG. 2.

FIG. 5 is a schematic structural view of a first embodiment of a connecting hole and a conductive groove according to the present disclosure.

FIG. 6 is a schematic structural view of a second embodiment of a connecting hole and a conductive groove according to the present disclosure.

FIG. 7 is a schematic structural sectional view at H-H in FIG. 1 according to a first embodiment.

FIG. 8 is a schematic structural sectional view at H-H in FIG. 1 according to a second embodiment.

FIG. 9 is a schematic structural sectional view at H-H in FIG. 1 according to a third embodiment.

FIG. 10 is a schematic structural view of a second embodiment of a display panel according to the present disclosure.

FIG. 11 is a schematic structural sectional view at M-M in FIG. 10 according to some embodiments of the present disclosure.

FIG. 12 is a schematic structural view of a third embodiment of a display panel according to the present disclosure.

FIG. 13 is a schematic structural sectional view at N-N in FIG. 12 according to some embodiments of the present disclosure.

FIG. 14 is a schematic structural view of a device with an under screen camera according to some embodiments of the present disclosure.

### DETAILED DESCRIPTION

The following provides a detailed description of the technical solutions in some embodiments of the present disclosure with reference to the accompanying drawings.

In the following description, specific details such as particular system structures, interfaces, and technologies are presented for illustrative purposes and not for the purpose of limitation, to provide a thorough understanding of the present disclosure.

The technical solutions in some embodiments of the present disclosure will be clearly and completely described below with reference to the accompanying drawings. It is evident that the described embodiments are only part of the embodiments of the present disclosure and not all embodiments. Based on the embodiments of the present disclosure, all other embodiments obtained by those skills in the art without any creative work fall within the scope of the present disclosure.

The terms “first”, “second”, and “third” in some embodiments of the present disclosure are merely used for descriptive purposes and should not be construed as indicating or implying relative importance or implicitly indicating the quantity of the indicated technical features. Thus, the features limited by “first” “second” and “third” may explicitly or implicitly include at least one such feature. In the description of the present disclosure, “a plurality of” means at least two, for example, two, three, etc., unless specifically and explicitly limited otherwise. All directional indications (such as up, down, left, right, front, back, etc.) in the embodiments of the present disclosure are only used to explain the relative positional relationships, motion situations, etc. among the components under a specific posture (as shown in the figures). When the specific posture changes, the directional indications shall be changed accordingly. Furthermore, the terms “including” and “having” and any variations thereof, are intended to cover non-exclusive inclusion. For example, a process, method, system, product, or device that includes a series of steps or units is not limited to those explicitly listed steps or units but may further optionally include other steps or units not listed, or may further optionally include other inherent steps or units of such process, method, product, or device.

As referred to herein, “embodiment” means that a specific feature, structure, or characteristic described in connection with the embodiment may be included in at least one embodiment of the present disclosure. The appearance of the phrase in various places in the specification are not necessarily all referring to the same embodiment, nor are they mutually exclusive alternative embodiments. It is explicitly and implicitly understood by those skills in the art that the embodiments described herein may be combined with other embodiments.

Furthermore, it is to be understood that the use of the term “substantially” herein, unless otherwise defined with respect to a specific context, with respect to a numeric quantity or otherwise quantifiable relationship, e.g., perpendicularity or parallelism, is to be understood as indicating that quantity +−10%. Thus, for example, lines that are substantially perpendicular to one another may be at angles between 81° and 99° to one another. In a further example, dimensions that are substantially between 1 mm and 3 mm, for example, may range from 0.9 mm to 3.3 mm. In another example, an angle that is substantially in the range of 1 to 1.1 radians may be between 0.9 radians and 1.21 radians.

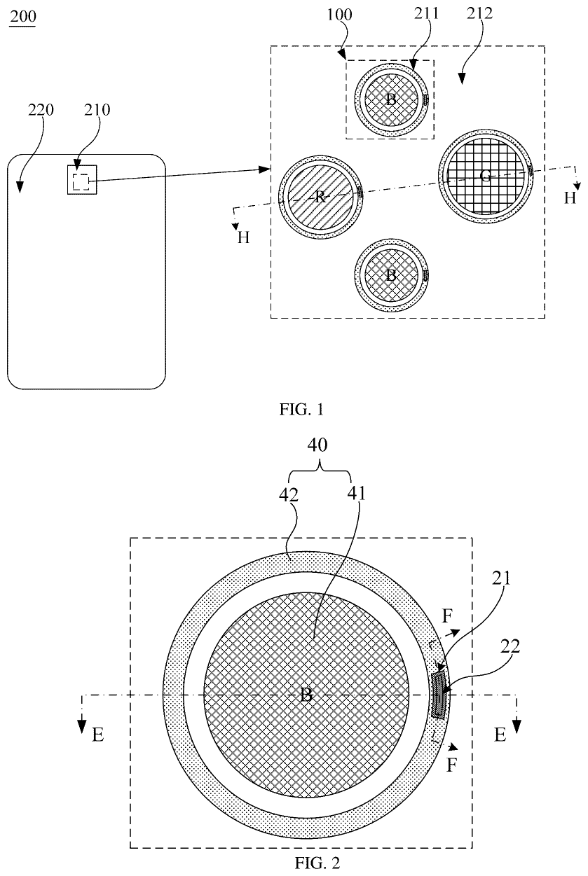

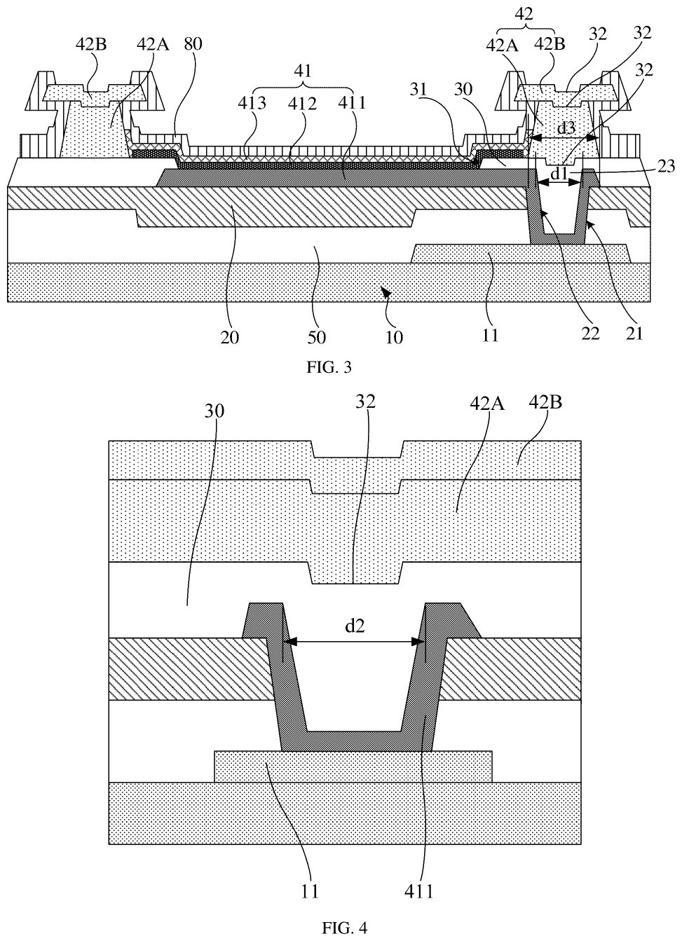

As shown in FIGS. 1-4, FIG. 1 is a schematic structural view of a first embodiment of a display panel according to the present disclosure, FIG. 2 is an enlarged schematic structural view of a pixel structure according to some embodiments of the present disclosure, FIG. 3 is a schematic structural sectional view at E-E in FIG. 2, and FIG. 4 is a schematic structural sectional view at F-F in FIG. 2.

Some embodiments of the present disclosure may provide a display panel 200. The display panel 200 may be configured in a device with an under screen camera. The display panel 200 may include an under screen camera area 210. The under screen camera area 210 may include a plurality of pixel areas 211 and a light-transmitting area 212 disposed at a side of the plurality of pixel areas 211. In some embodiments, as shown in FIG. 1, the light-transmitting area 212 may surround the plurality of pixel areas 211. The display panel 200 may include a plurality of pixel structures 100. The plurality of pixel structures 100 may be disposed in the plurality of pixel areas 211. Each of the plurality of pixel structures 100 may be disposed in a corresponding one of the plurality of pixel areas 211. Each pixel area 211 may include a pixel driving layer 10, a planarization layer 20, a pixel defining layer 30, and a sub-pixel unit 40 that are sequentially stacked on one another. The planarization layer 20 may define a connecting hole 21 and the number of the connecting hole 21 may be more than one. The pixel defining layer 30 may define a plurality of pixel openings 31. Each sub-pixel unit 40 may include a sub-pixel 41 and an isolation structure 42. The sub-pixel 41 of each sub-pixel unit 40 may be disposed in a corresponding one of the plurality of pixel openings 31. An anode 411 of the sub-pixel 41 may be electrically connected to the pixel driving layer 10 through the connecting hole 21. The isolation structure 42 of each sub-pixel unit 40 may protrude from the pixel defining layer 30 and surround or encircle a corresponding one of the plurality of pixel openings 31. The isolation structure 42 may be electrically connected to a cathode 413 of the sub-pixel 41 encircled therein. The sub-pixel 41 may be substantially circular or elliptical in shape. An orthographic projection of the isolation structure 42 on the planarization layer 20 may cover the connecting hole 21. That is, the connecting hole 21 may be located within the orthographic projection of the isolation structure 42 on the planarization layer 20. In some embodiments, the planarization layer 20 may extend to the light-transmitting area 212, and the connecting hole 21 may be defined in the light-transmitting area 212. In some embodiments, the planarization layer 20 may further extend to the light-transmitting area 212, and a part of the connecting hole 21 may be defined in a corresponding one of the plurality of pixel areas 211 and another part of the connecting hole 21 may be defined in the light-transmitting area 212. An orthographic projection of the isolation structure 42 projected on the planarization layer 20 may cover the part of the connecting hole 21 located in the corresponding one of the plurality of pixel areas 211. That is, the part of the connecting hole 21 defined in the corresponding pixel area 211 may be located within the orthographic projection of the isolation structure 42 on the planarization layer 20.

Through arranging the connecting hole 21 to be at least partially under the isolation structure 42 and a part of the connecting hole 21 that is not under the isolation structure 42 to be within the light-transmitting area 212, or through arranging the connecting hole 21 to be entirely within in the light-transmitting area 212, the connecting hole 21 may be defined as far from the corresponding one of the plurality of pixel openings 31 as possible without affecting a size of the corresponding one of the plurality of pixel openings 31. As a result, during deposition of the anode 411, a surface of the anode 411 at the corresponding one of the plurality of pixel openings 31 may not be rendered uneven and lead to reduced flatness which is caused by partial deposition over the connecting hole 21, thereby reducing a risk of reduced luminance or degraded viewing-angle performance of the sub-pixel 41 and improving the light-emitting performance of the display panel 200. In addition, designing the sub-pixel 41 in substantially a circular or elliptical shape may ensure that an edge of the sub-pixel 41 has no right angles or sharp corners, which may reduce a diffraction effect in the display panel 200.

The plurality of pixel areas 211 may be spaced apart from each other by the light-transmitting area 212. The plurality of pixel areas 211 may be configured to display an image. The light-transmitting area 212 may be configured to transmit light. The under screen camera area 210 may further be referred to as a light-transmitting display area.

It should be understood that the display panel 200 may further include a primary display area 220 located at a side of the under screen camera area 210. A distribution of the sub-pixels 41 in the primary display area 220 and the under screen camera area 210 may not be limited herein and may be selected based on actual needs.

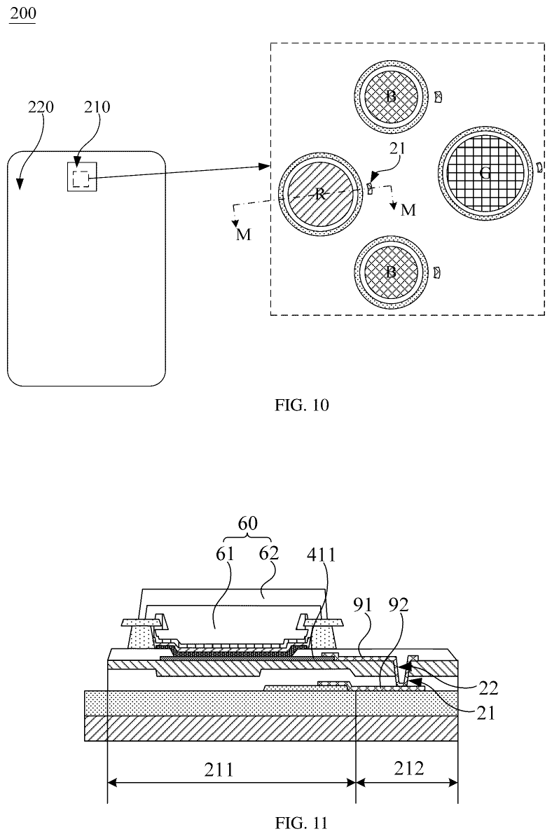

In a direction substantially parallel to the pixel defining layer 30, a cross-section of each pixel structure 100 may be substantially circular or elliptical in shape. One pixel structure 100 may be arranged in each pixel area 211. It can be understood that each pixel area 211 may be substantially circular or elliptical in shape, so that an edge of the light-transmitting area 212 has no right angles or sharp corners, which facilitates in reducing an impact of light diffraction on a light-sensing element (e.g., a camera module 300 as shown in FIG. 10) under the display in the device with the under screen camera, thereby improving the display performance of the display panel 200.

In some embodiments, a case where the cross-section of each pixel structure 100 is circular in the direction substantially parallel to the pixel defining layer 30 is described as an example.

The pixel driving layer 10, the planarization layer 20, and the pixel defining layer 30 may be disposed in each pixel area 211 to reduce film structures in the light-transmitting area 212, which helps improve the light transmittance of the light-transmitting area 212 and ensures the imaging performance of the under screen camera area 210, thereby enabling the under screen camera area 210 to have both light-transmitting and display functions.

The pixel driving layer 10 may be configured to drive the sub-pixel 41 to emit light. A structure of the pixel driving layer 10 is not limited herein and may be selected based on actual needs.

The pixel driving layer 10 may include an output electrode 11. The anode 411 may be connected to the output electrode 11 of the pixel driving layer 10 through the connecting hole 21.

The planarization layer 20 may define the connecting hole 21. In a direction substantially perpendicular to the pixel driving layer 10, the connecting hole 21 may penetrate the planarization layer 20. In the direction substantially perpendicular to the planarization layer 20, a cross-section of the connecting hole 21 may be an inverted trapezoid. A diameter of an end of the connecting hole 21 that is close to the pixel driving layer 10 may be smaller than a diameter of another end of the connecting hole 21 that is away from the pixel driving layer 10. The above configuration of the connecting hole 21 may facilitate the anode 411 in covering a sidewall of the connecting hole 21 to establish an electrical connection with the pixel driving layer 10.

A material of the planarization layer 20 is not limited herein and may be selected based on actual needs.

The pixel defining layer 30 may define a position of the sub-pixel 41. In the direction substantially perpendicular to the pixel driving layer 10, the plurality of pixel openings 31 may penetrate the pixel defining layer 30 and expose at least part of the anode 411, so that a light-emitting layer 412 and the cathode 413 of the sub-pixel 41 may be sequentially disposed on a side of the anode 411 away from the pixel driving layer 10.

After the anode 411 is formed, the pixel defining layer 30 may be formed on a side of the planarization layer 20 away from the pixel driving layer 10. The pixel defining layer 30 may cover a conductive groove 22. Due to the manufacturing process of the pixel defining layer 30, a recess 32 may be defined on a surface of a part of the pixel defining layer 30 corresponding to the conductive groove 22 and away from the pixel driving layer 10. That is, the surface of the side of the pixel defining layer 30 away from the conductive groove 22 may be non-flat, such that a conductive portion 42A and a shielding structure or eave structure 42B disposed later at the recess 32 may, respectively, have the recess 32 on a side away from the pixel driving layer 10.

The display panel 200 may further include an insulating layer 50. The insulating layer 50 may be disposed between the pixel driving layer 10 and the planarization layer 20. In the direction substantially perpendicular to the pixel driving layer 10, the connecting hole 21 may penetrate the insulating layer 50 to partially expose the output electrode 11 of the pixel driving layer 10, enabling the anode 411 to be electrically connected to the output electrode 11 through the connecting hole 21.

It can be understood that the insulating layer 50 and the planarization layer 20 may cooperatively define the connecting hole 21.

It should be noted that in some embodiments of the present disclosure, the planarization layer 20 in each pixel structure 100 may be formed through patterning a same material layer. The pixel defining layer 30 in each pixel structure 100 may be formed through patterning a same material layer. The insulating layer 50 in each pixel structure 100 may be formed through patterning a same material layer.

Each sub-pixel unit 40 may be arranged in a corresponding one of the pixel structures 100. Each sub-pixel unit 40 may include one sub-pixel 41 and one isolation structure 42. A shape of each sub-pixel 41 may determine a shape of the corresponding one of the plurality of pixel structures 100. When the sub-pixel 41 is substantially circular in shape, a cross-section of the isolation structure 42 in the direction substantially parallel to the pixel defining layer 30 may be substantially circular in shape. When the sub-pixel 41 is substantially elliptical in shape, the cross-section of the isolation structure 42 in the direction substantially parallel to the pixel defining layer 30 may be substantially elliptical in shape.

In some embodiments, the sub-pixel 41 may be described as being substantially circular in shape as an example.

For each sub-pixel 41, the sub-pixel 41 may be surrounded by the isolation structure 42. A shape of the sub-pixel 41 may be similar to a shape of an area encircled or surrounded by the isolation structure 42. In the direction substantially parallel to the pixel defining layer 30, an edge of the isolation structure 42 and an edge of the sub-pixel 41 that are adjacent to each other may be substantially arranged in parallel. In this way, a shape of the sub-pixel 41 may be ensured to be similar to a shape of a cross-section of the corresponding pixel structure 100 in the direction substantially parallel to the pixel defining layer 30, which helps reduce the diffraction effect in the display panel 200.

The sub-pixel 41 may include an OLED. In some embodiments, the sub-pixel 41 may include the anode 411, the light-emitting layer 412, and the cathode 413 that are sequentially disposed or stacked on one another. The anode 411 may be disposed between the planarization layer 20 and the pixel defining layer 30.

The anode 411 may be disposed in a corresponding one of the plurality of pixel openings 31, extend into the connecting hole 21, and cover the sidewall of the connecting hole 21, so as to be electrically connected to the pixel driving layer 10 through the connecting hole 21. A part of the anode 411 located in the connecting hole 21 may surround and define the conductive groove 22. That is, a part of the anode 411 may be disposed in the corresponding one of the plurality of pixel openings 31, and another part of the anode 411 may be deposited in the connecting hole 21 to be electrically connected with the pixel driving layer 10. The anode 411 deposited in the connecting hole 21 may cover the sidewall of the connecting hole 21. The part of the anode 411 covering the sidewall of the connecting hole 21 and the part of the anode 411 in contact with the pixel driving layer 10 may together or cooperatively surround and define the conductive groove 22.

It can be understood that the part of the anode 411 located in the connecting hole 21 may be prone to material accumulation and step coverage issues during the deposition process, rendering uneven film thickness in the part of the anode 411. In a case where the connecting hole 21 is defined below the pixel opening 31, a decrease in the flatness of the anode 411 at the pixel opening 31 may be likely caused, leading to uneven film thickness of the light-emitting layer 412 in the pixel opening 31, thereby affecting the light-emitting effect of the sub-pixel 41. In some embodiments, the connecting hole 21 may be defined below the isolation structure 42, so that during the deposition of the anode 411, the deposition of the part of the anode 411 into the connecting hole 21 may not result in an uneven surface or reduced flatness of the anode 411 in the pixel opening 31.

The display panel 200 may include the sub-pixels 41 of three different colors. The sub-pixels 41 of three different colors may include a red pixel R, a green pixel G, and a blue pixel B. An arrangement manner of the sub-pixels 41 in the display panel 200 is not limited herein and may be selected based on actual needs.

It can be understood that in other embodiments, the display panel 200 may include the sub-pixel 41 of at least one color. The sub-pixel 41 may further be a sub-pixel of other colors.

As shown in FIGS. 1-6, FIG. 5 is a schematic structural view of a first embodiment of a connecting hole and a conductive groove according to the present disclosure, and FIG. 6 is a schematic structural view of a second embodiment of a connecting hole and a conductive groove according to the present disclosure.

The conductive groove 22 may be arranged in one-to-one correspondence with the connecting hole 21. That is, one conductive groove 22 may correspond to one sub-pixel 41. A projection of the conductive groove 22 on the pixel driving layer 10 may be located within a projection of the connecting hole 21 on the pixel driving layer 10. A projection pattern of the conductive groove 22 on the pixel driving layer 10 may be similar to a projection pattern of the connecting hole 21 on the pixel driving layer 10. Adjacent edges of the two projection patterns may be substantially arranged in parallel.

In the direction substantially perpendicular to the pixel driving layer 10, the isolation structure 42 may include the conductive portion 42A and the shielding structure 42B that are disposed or stacked on one another in sequence. The shielding structure 42B may shield the conductive portion 42A and extend beyond the conductive portion 42A in a direction substantially parallel to a plane where the pixel defining layer 30 is located. That is, an orthographic projection of the shielding structure 42B on the pixel driving layer 10 may cover an orthographic projection of the conductive portion 42A on the pixel driving layer 10. In other words, the orthographic projection of the conductive portion 42A on the pixel driving layer 10 may be located within the orthographic projection of the shielding structure 42B on the pixel driving layer 10. An area of the orthographic projection of the shielding structure 42B on the pixel driving layer 10 may be greater than an area of the orthographic projection of the conductive portion 42A on the pixel driving layer 10. The cathode 413 of each sub-pixel 41 may be electrically connected with each other through the conductive portion 42A. The shielding structure 42B may be configured to adjust a deposition angle of a deposition material during the deposition of the cathode 413 and the light-emitting layer 412 of the sub-pixel 41, so that the cathode 413 may cover the light-emitting layer 412 and be well electrically connected to the conductive portion 42A.

A material of the shielding structure 42B is not limited herein and may be selected based on actual needs. In the direction substantially perpendicular to the pixel driving layer 10, a width of the conductive portion 42A may gradually decrease in a direction toward or approaching the shielding structure 42B, facilitating in the cathode 413 to lap with a side surface of the conductive portion 42A.

Further, the orthographic projection of the conductive portion 42A on the pixel driving layer 10 may cover the orthographic projection of the conductive groove 22 on the pixel driving layer 10. In other words, the orthographic projection of the conductive groove 22 on the pixel driving layer 10 may be located within the orthographic projection of the conductive portion 42A on the pixel driving layer 10. The conductive portion 42A may include a metal layer that is opaque. Through defining the conductive groove 22 below the conductive portion 42A, the conductive groove 22 may be located as far away as possible from the corresponding one of the plurality of pixel openings 31 without affecting the size of the pixel opening 31, thereby facilitating in reducing the occurrence of reduced flatness of the anode 411 at the corresponding one of the plurality of pixel openings 31.

The isolation structures 42 may be arranged in one-to-one correspondence with the sub-pixels 41 and in one-to-one correspondence with the plurality of pixel structures 100. In the direction substantially parallel to the pixel defining layer 30, the conductive groove 22 may extend along a surrounding direction of the corresponding isolation structure 42. The surrounding direction of the isolation structure 42 may refer to a direction where the isolation structure 42 surrounds the pixel opening 31. A width direction of the conductive groove 22 may be a wall thickness direction of the corresponding isolation structure 42. A width of a groove opening 23 of the conductive groove 22 may be defined as a first size d1. The first size d1 may be less than 4 μm, i.e., d1<4 μm. The above design may ensure a good electrical connection between the anode 411 and the pixel driving layer 10 while maintaining the size of the corresponding one of the plurality of pixel openings 31 and the spacing between the sub-pixels 41 unchanged, and further minimizes the width of the conductive groove 22 to maximize the distance between the corresponding one of the plurality of pixel openings 31 and the conductive groove 22, thereby reducing the influence of the anode 411 at the connecting hole 21 on the flatness of the anode 411 at the corresponding one of the plurality of pixel openings 31.

A length direction of the conductive groove 22 may correspond to the surrounding direction of the isolation structure 42. An extending length of the conductive groove 22 from an end of the groove opening 23 of the conductive groove 22 to another other end of the groove opening 23 of the conductive groove 22 in the length direction may be defined as a second size d2. The second size d2 may be greater than the first size d1. The above design may increase the extending length of the conductive groove 22 in the surrounding direction of the isolation structure 42 without affecting the size of the pixel opening 31, thereby increasing an area of the cross-section of the conductive groove 22 in the direction substantially parallel to the planarization layer 20, which facilitates in increasing a contact area between the anode 411 at the connecting hole 21 and the output electrode 11, thereby ensuring the good electrical connection between the anode 411 and the pixel driving layer 10.

In the wall thickness direction of the isolation structure 42, adjacent edges of the conductive portion 42A and the corresponding conductive groove 22 may be substantially arranged in parallel.

It can be understood that a pattern formed by an orthographic projection of the conductive groove 22 on the pixel driving layer 10 may be a first projection pattern. A pattern formed by an orthographic projection of the conductive portion 42A on the pixel driving layer 10 may be a second projection pattern. In the width direction of the conductive groove 22, an edge of the first projection pattern and an adjacent edge of the corresponding second projection pattern may be substantially arranged in parallel. The above design may not only facilitate in the formation of the conductive groove 22 but also enable the width of the conductive groove 22 to be increased within an allowable range of the conductive groove 22 (i.e., d1<4 μm) without changing the size of the conductive portion 42A, thereby increasing an area of the cross-section of the conductive groove 22 in the direction substantially parallel to the planarization layer 20.

In the wall thickness direction of the isolation structure 42, a width of an end of the conductive portion 42A away from the shielding structure 42B may be defined as a third size d3. The third size d3 may be greater than the first size d1, ensuring that a bottom of the conductive portion 42A may cover the conductive groove 22.

In a direction directed from the groove opening 23 of the conductive groove 22 to a bottom wall of the conductive groove 22, the width of the conductive groove 22 may gradually decrease. The groove opening 23 of the conductive groove 22 may be located at an end of the conductive groove 22 away from the pixel driving layer 10.

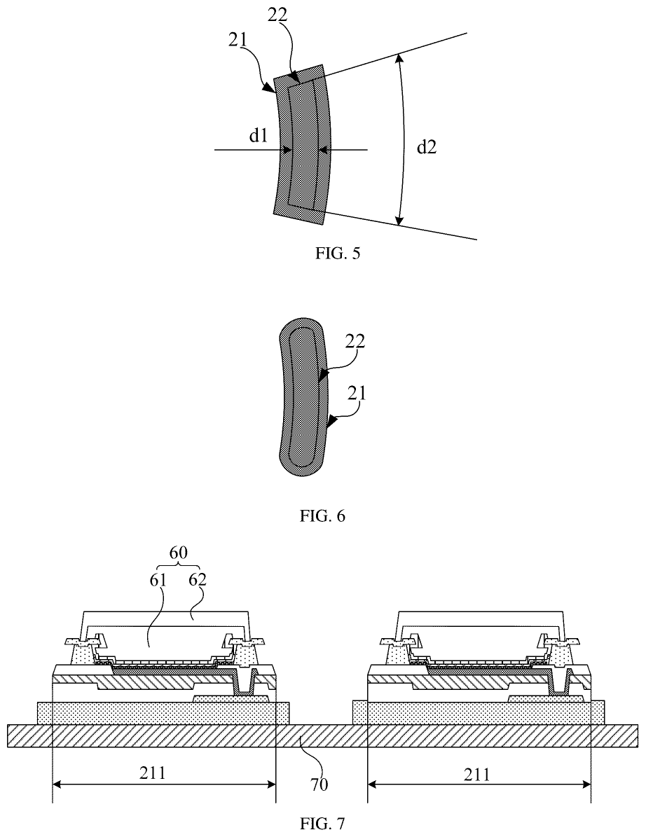

In some embodiments, in the length direction of the conductive groove 22, a side edge of the groove opening 23 of the conductive groove 22 may extend linearly or in a straight line (as shown in FIG. 5). In some embodiments, in the length direction of the conductive groove 22, the side edge of the groove opening 23 of the conductive groove 22 may extend in a curved line (as shown in FIG. 6).

In some embodiments, in the length direction of the conductive groove 22, the side edge of the groove opening 23 of the conductive groove 22 may extend in a straight line.

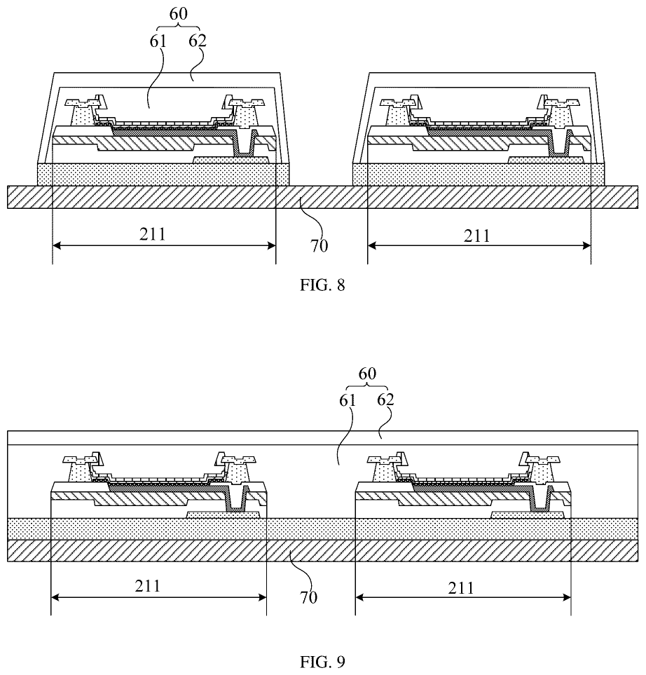

As shown in FIGS. 1-9, FIG. 7 is a schematic structural sectional view at H-H in FIG. 1 according to a first embodiment, FIG. 8 is a schematic structural sectional view at H-H in FIG. 1 according to a second embodiment, and FIG. 9 is a schematic structural sectional view at H-H in FIG. 1 according to a third embodiment.

The display panel 200 may further include an encapsulation layer 60 and a substrate 70. The substrate 70 may be disposed on a side of the pixel driving layer 10 away from the pixel defining layer 30. The encapsulation layer 60 may be disposed on a side of the plurality of pixel structures 100 away from the substrate 70 and may encapsulate at least the sub-pixel 41 of each pixel structure 100.

The substrate 70 may include a polyimide film and/or a glass substrate. In a case where the substrate 70 includes the glass substrate, the light transmittance of the light-transmitting area 212 may be further improved. In a case where the substrate 70 includes the polyimide film (a flexible PI film), the flexibility of the display panel 200 may be further improved, and the sub-pixel 41 may further be individually encapsulated, which may reduce the film structures of the light-transmitting area 212, thereby improving the light transmittance of the light-transmitting area 212. In a case where the substrate 70 includes both the glass substrate and the polyimide film, the glass substrate and the polyimide film may be located at a same layer, and the display panel 200 may be a stretchable display panel.

In some embodiments, the encapsulation layer 60 may be disposed on the plurality of pixel areas 211 and cover each sub-pixel 41. The encapsulation layer 60 may further extend to the corresponding isolation structure 42 and cover a part of a surface of the corresponding isolation structure 42 that is away from the pixel driving layer 10 (as shown in FIG. 7). In some embodiments, the encapsulation layer 60 may be disposed on the plurality of pixel areas 211 and may cover a surface of a side of each sub-pixel unit 40 that is away from the pixel driving layer 10 and further cover a side surface of each sub-pixel unit 40 (as shown in FIG. 8). In some embodiments, the encapsulation layer 60 may be disposed on both the plurality of pixel areas 211 and the light-transmitting area 212 and may cover the substrate 70 (as shown in FIG. 9).

It should be understood that in a case where the encapsulation layer 60 is disposed on the plurality of pixel areas 211, covers each sub-pixel 41, and further extends to the isolation structure 42 and covers a part of a surface of the isolation structure 42 that is away from the pixel driving layer 10, or in a case where the encapsulation layer 60 is disposed on the plurality of pixel areas 211 and covers the surface of the side of each sub-pixel unit 40 that is away from the pixel driving layer 10 and the side surface of each sub-pixel unit 40, the encapsulation layer 60 may provide an independent encapsulation for each sub-pixel 41, and the encapsulation layer 60 in the light-transmitting area 212 may be omitted. That is, the film layer structures of the light-transmitting area 212 may be reduced, which may facilitate improving the light transmittance of the light-transmitting area 212 and further contribute to enhance the flexibility of the display panel 200.

The encapsulation layer 60 may include a first encapsulation layer 61 and a second encapsulation layer 62. The second encapsulation layer 62 may be disposed on a side of the first encapsulation layer 61 away from the pixel defining layer 30. A structure of the encapsulation layer 60 is not limited herein and may be selected based on actual needs.

The display panel 200 may further include a protection layer 80. The protection layer 80 may be disposed in the plurality of pixel areas 211. The protection layer 80 may cover a surface of a side of each sub-pixel 41 that is away from the pixel driving layer 10 and extend to a part of a surface of a side of the isolation structure 42 that is away from the pixel driving layer 10. In addition, the protection layer 80 may be further disposed on a side of the encapsulation layer 60 that is close to the pixel driving layer 10. The protection layer 80 may be configured to provide an isolation protection for the sub-pixel 41 during the manufacturing process of the sub-pixel 41.

As shown in FIGS. 1-4 and 10-11, FIG. 10 is a schematic structural view of a second embodiment of a display panel according to the present disclosure, and FIG. 11 is a schematic structural sectional view at M-M in FIG. 10 according to some embodiments of the present disclosure.

Compared with the first embodiment of the display panel 200 provided by the present disclosure, the second embodiment of the display panel 200 provided by the present disclosure may be substantially similar in structure, with the difference being that: the planarization layer 20 may further extend to the light-transmitting area 212 and the connecting hole 21 may be defined in the light-transmitting area 212.

In some embodiments, the planarization layer 20 may further extend to the light-transmitting area 212 and the connecting hole 21 may be defined in the light-transmitting area 212.

The display panel 200 may further include a first transparent conductive wiring layer 91 and a second transparent conductive wiring layer 92.

The first transparent conductive wiring layer 91 may be disposed between the pixel defining layer 30 and the planarization layer 20. An end of the first transparent conductive wiring layer 91 may lap with the anode 411. Another end of the first transparent conductive wiring layer 91 may extend into the connecting hole 21 and cover the sidewall of the connecting hole 21. A part of the first transparent conductive wiring layer 91 located in the connecting hole 21 may surround and define the conductive groove 22. The conductive groove 22 may be arranged in one-to-one correspondence with the connecting hole 21.

The second transparent conductive wiring layer 92 may be disposed between the pixel driving layer 10 and the planarization layer 20. An end of the second transparent conductive wiring layer 92 may lap with the output electrode 11 of the pixel driving layer 10. Another end of the second transparent conductive wiring layer 92 may extend to the bottom of the connecting hole 21 to lap with the conductive groove 22.

The first transparent conductive wiring layer 91 may include one or a combination of the following: an indium tin oxide, an indium zinc oxide, an aluminum-doped zinc oxide, an indium gallium zinc oxide, a zinc oxide, and a zinc manganese oxide. The second transparent conductive wiring layer 92 may include one or a combination of the following: an indium tin oxide, an indium zinc oxide, an aluminum-doped zinc oxide, an indium gallium zinc oxide, a zinc oxide, and a zinc manganese oxide. A material of the first transparent conductive wiring layer 91 and a material the second transparent conductive wiring layer 92 may be the same or different, which are not limited herein and may be selected based on actual needs.

In some embodiments, each of the first transparent conductive wiring layer 91 and the second transparent conductive wiring layer 92 is an indium stannum tin oxide (ITO).

The anode 411 may be electrically connected to the pixel driving layer 10 through the first transparent conductive wiring layer 91, the second transparent conductive wiring layer 92, and the output electrode 11 in sequence.

The first transparent conductive wiring layer 91 and the second transparent conductive wiring layer 92 may be configured in transparent, thereby ensuring the light transmittance of the light-transmitting area 212.

It should be noted that when the conductive groove 22 is defined in the light-transmitting area 212, then an extending direction of the conductive groove 22, a shape of the conductive groove 22, and a width of the conductive groove 22 may not be required to be associated with the isolation structure 42. In other words, a shape and a size of the conductive groove 22 may be designed based on an area of the light-transmitting area 212, which are not limited herein and may be selected based on actual needs.

The display panel 200 may further include the insulating layer 50. The insulating layer 50 may be disposed between the pixel driving layer 10 and the planarization layer 20 and cover the second transparent conductive wiring layer 92. In the direction substantially perpendicular to the pixel driving layer 10, the connecting hole 21 may penetrate the insulating layer 50 to partially expose the output electrode 11 of the pixel driving layer 10, such that the anode 411 may be electrically connected to the output electrode 11 through the connecting hole 21.

It can be understood that the insulating layer 50 and the planarization layer 20 may together or cooperatively define the connecting hole 21.

Compared with the first embodiment of the display panel 200 provided by the present disclosure, the present embodiment may allow or enable the connecting hole 21 to be defined further away from the plurality of pixel openings 31, which may not only increase a design space of the anode 411 but also further help improve the flatness of the anode 411.

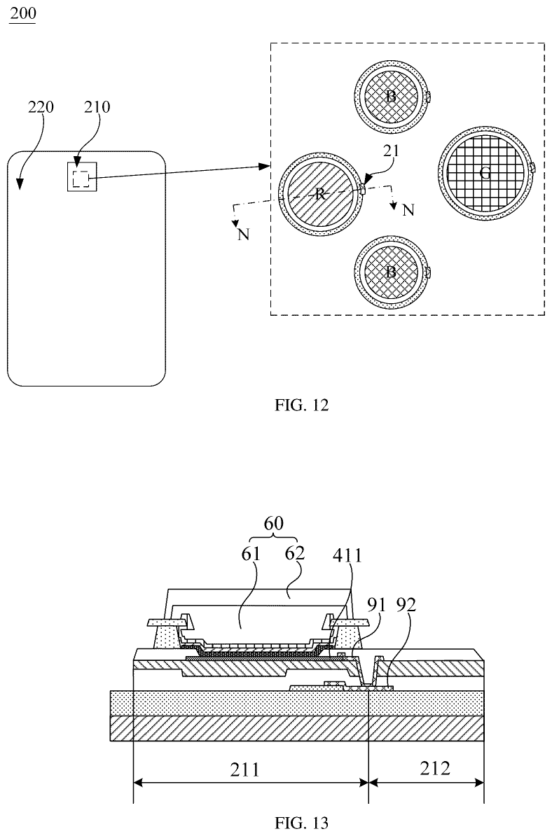

As shown in FIGS. 1-4 and 10-13, FIG. 12 is a schematic structural view of a third embodiment of a display panel according to the present disclosure, and FIG. 13 is a schematic structural sectional view at N-N in FIG. 12 according to some embodiments of the present disclosure.

Compared with the second embodiment of the display panel 200 provided by the present disclosure, the third embodiment of the display panel 200 provided by the present disclosure may be substantially similar in structure, with the difference being that: a part of the connecting hole 21 may be defined in a corresponding one of the plurality of pixel areas 211 and another part of the connecting hole 21 may be defined in the light-transmitting area 212. An orthographic projection of the isolation structure 42 on the planarization layer 20 may cover the part of the connecting hole 21 that is defined in the corresponding one of the plurality of pixel areas 211. That is, the part of the connecting hole 21 that is defined in the corresponding one of the plurality of pixel areas 211 may be located within the orthographic projection of the isolation structure 42 on the planarization layer 20.

In some embodiments, the planarization layer 20 may further extend to the light-transmitting area 212. A part of the connecting hole 21 may be defined in the corresponding one of plurality of pixel areas 211 and another part of the connecting hole 21 may be defined in the light-transmitting area 212. The orthographic projection of the isolation structure 42 on the planarization layer 20 may cover the part of the connecting hole 21 that is defined in the corresponding one of the plurality of pixel areas 211.

In some embodiment, the display panel 200 may further include the first transparent conductive wiring layer 91 and the second transparent conductive wiring layer 92.

The first transparent conductive wiring layer 91 may be disposed between the pixel defining layer 30 and the planarization layer 20. An end of the first transparent conductive wiring layer 91 may lap with the anode 411. Another end of the first transparent conductive wiring layer 91 may extend into the connecting hole 21 and cover the sidewall of the connecting hole 21. A part of the first transparent conductive wiring layer 91 located in the connecting hole 21 may surround and define the conductive groove 22. The conductive groove 22 may be arranged in one-to-one correspondence with the connecting hole 21.

The second transparent conductive wiring layer 92 may be disposed between the pixel driving layer 10 and the planarization layer 20. An end of the second transparent conductive wiring layer 92 may lap with the output electrode 11 of the pixel driving layer 10. Another end of the second transparent conductive wiring layer 92 may extend to the bottom of the connecting hole 21 to lap with the conductive groove 22.

Compared with the first embodiment of the display panel 200 provided by the present disclosure, the present embodiment may allow or enable the connecting hole 21 to be disposed further away from the plurality of pixel openings 31, which may not only increase the design space of the anode 411 but also further help improve the flatness of the anode 411. Compared with the display panel 200 provided by the second embodiment of the present disclosure, only a part of the connecting hole 21 in the present embodiment may be defined in the corresponding one of the plurality of pixel areas 211.

A shape and a size of the connecting hole 21 are not limited herein and may be selected based on actual needs, as long as the orthographic projection of the isolation structure 42 on the planarization layer 20 covers the part of the connecting hole 21 that is defined in the corresponding one of the plurality of pixel areas 211.

It should be noted that the various configurations of the encapsulation layer 60 described above may be further applicable to the second and third embodiments of the display panel 200 provided by the present disclosure, which will not be repeated herein and may refer to the above descriptions.

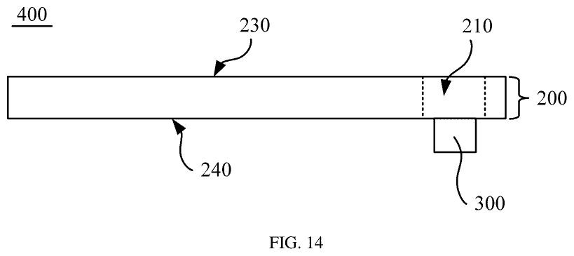

As shown on FIG. 14, FIG. 14 is a schematic structural view of a device with an under screen camera according to some embodiments of the present disclosure.

Some embodiments of the present disclosure may provide a device 400 with under screen camera. The device 400 with under screen camera may include the display panel 200 and the camera module 300. The display panel 200 may be the aforementioned display panel 200. The display panel 200 may have a display side 230 and a non-display side 240 that are disposed opposite to each other. The camera module 300 may be disposed on the non-display side 240 of the display panel 200 and arranged corresponding to or under the under screen camera area 210.

The camera module 300 may include a camera. The camera may be a front-facing camera. When the camera is in use, the under screen camera area 210 may not display an image, thereby allowing or enabling the camera to capture an image. When the camera is not in use, the under screen camera area 210 may display an image, thereby increasing a screen-to-body ratio while retaining the camera functionality.

In the above embodiments, different aspects are emphasized respectively. A part that is not described in detail in one embodiment may refer to relevant descriptions in other embodiments.

The above are merely exemplary embodiments of the present disclosure and should not be construed as limiting the scope of the present disclosure. Based on the description and drawings of the present disclosure, any equivalent structural or process modifications, or any direct or indirect applications in other related technical fields, shall fall within the scope of the present disclosure.

1. A display panel, configured in a device with an under screen camera, the display panel having an under screen camera area, the under screen camera area comprising a plurality of pixel areas and a light-transmitting area disposed at a side of the plurality of pixel areas, and the display panel comprising:
a plurality of pixel structures, disposed in the plurality of pixel areas, wherein each of the plurality of pixel structures is disposed in a corresponding one of the plurality of pixel areas, each of the plurality of pixel areas comprises a pixel driving layer, a planarization layer, a pixel defining layer, and a sub-pixel unit that are sequentially stacked on one another, the planarization layer defines a plurality of connecting holes, and the pixel defining layer defines a plurality of pixel openings;
wherein each sub-pixel unit comprises:
a sub-pixel, disposed in a corresponding one of the plurality of pixel openings, wherein an anode of the sub-pixel is electrically connected to the pixel driving layer through a corresponding one of the plurality of connecting holes; and
an isolation structure, protruding from the pixel defining layer and surrounding the corresponding one of the plurality of pixel openings, wherein the isolation structure is electrically connected to a cathode of the sub-pixel surrounded by the isolation structure;
wherein the sub-pixel is substantially circular or elliptical in shape;
wherein each of the plurality of connecting holes is located within an orthographic projection of the corresponding isolation structure on the planarization layer;
or,
the planarization layer further extends to the light-transmitting area, and the plurality of connecting holes are defined in the light-transmitting area;
or,
the planarization layer further extends to the light-transmitting area, a part of each of the plurality of connecting holes is defined in a corresponding one of the plurality of pixel areas, another part of each of the plurality of connecting holes is defined in the light-transmitting area, and the part of each of the plurality of connecting holes defined in the plurality of pixel areas is located within an orthographic projection of the corresponding isolation structure on the planarization layer.

2. The display panel as claimed in claim 1, wherein the anode is disposed in the corresponding one of the plurality of pixel openings, extends into the corresponding one of the plurality of connecting holes, and covers a sidewall of the corresponding one of the plurality of connecting holes to electrically connect to the pixel driving layer through the corresponding one of the plurality of connecting holes; and
a part of the anode disposed in the corresponding one of the plurality of connecting holes surrounds and defines a conductive groove, and the conductive groove is arranged in a one-to-one correspondence with the plurality of connecting holes.

3. The display panel as claim in claim 2, wherein in a direction substantially perpendicular to the pixel driving layer, the isolation structure comprises a conductive portion and a shielding structure sequentially stacked on one another; and
the shielding structure shields the conductive portion and extends beyond the conductive portion in a direction substantially parallel to a plane where the pixel defining layer is located, and an orthographic projection of the conductive groove on the pixel driving layer is located within an orthographic projection of the conductive portion on the pixel driving layer.

4. The display panel as claim in claim 3, wherein the isolation structure is arranged in an one-to-one correspondence with the sub-pixel, the isolation structure is arranged in an one-to-one correspondence with the plurality of pixel structures, and in a direction substantially parallel to the pixel defining layer, the conductive groove extends in a surrounding direction of the isolation structure; and
a width direction of the conductive groove refers to a wall thickness direction of the isolation structure corresponding to the conductive groove, a width of a groove opening of the conductive groove is a first size, and the first size is less than 4 μm.

5. The display panel as claim in claim 4, wherein a length direction of the conductive groove refers to the surrounding direction of the isolation structure; and
in the length direction, an extending length from an end of the groove opening to another end of the groove opening is a second size, and the second size is greater than the first size.

6. The display panel as claim in claim 3, wherein in a wall thickness direction of the isolation structure, an edge of the conductive portion and an edge of the corresponding conductive groove that are adjacent to each other are substantially arranged in parallel.

7. The display panel as claim in claim 4, wherein in a direction directed from the groove opening of the conductive groove to a bottom wall of the conductive groove, a width of the conductive groove gradually decreases; and
in a length direction of the conductive groove, an edge of the groove opening of the conductive groove extends in a straight line;
or,
in the length direction of the conductive groove, an edge of the groove opening of the conductive groove extends in a curved line.

8. The display panel as claim in claim 1, further comprising an encapsulation layer and a substrate, wherein the substrate is disposed on a side of the pixel driving layer away from the pixel defining layer, and the encapsulation layer is disposed on a side of the pixel structure away from the substrate and at least encapsulates the sub-pixel in each of the plurality of pixel structures;
the substrate comprises at least one of a polyimide film or a glass substrate; and
the encapsulation layer is disposed on the plurality of pixel areas, covers the sub-pixel, and extends to the isolation structure to cover a part of a surface of a side of the isolation structure that is away from the pixel driving layer;
or,
the encapsulation layer is disposed on the plurality of pixel areas, covers both a side of a surface of the sub-pixel unit that is away from the pixel driving layer, and further covers a side surface of the sub-pixel unit;
or,
the encapsulation layer is disposed on the plurality of pixel areas and the light-transmitting area, and the encapsulation layer covers the substrate.

9. The display panel as claim in claim 1, further comprising a first transparent conductive wiring layer and a second transparent conductive wiring layer;
wherein the first transparent conductive wiring layer is disposed between the pixel defining layer and the planarization layer, an end of the first transparent conductive wiring layer laps with the anode, another end of the first transparent conductive wiring layer extends into a corresponding one of the plurality of connecting holes and covers a sidewall of the corresponding one of the plurality of connecting holes, a part of the first transparent conductive wiring layer disposed in the corresponding one of the plurality of connecting holes surrounds and defines a conductive groove, and the conductive groove is arranged in a one-to-one correspondence with the plurality of connecting holes; and
the second transparent conductive wiring layer is disposed between the pixel driving layer and the planarization layer, an end of the second transparent conductive wiring layer laps with an output electrode of the pixel driving layer, and another end of the second transparent conductive wiring layer extends to a bottom of the corresponding one of the plurality of connecting holes to lap with the conductive groove.

10. The display panel as claim in claim 1, wherein an edge of the isolation structure and an edge of the sub-pixel that are adjacent to each other are substantially arranged in parallel.

11. A device with an under screen camera, comprising:
a display panel, the display panel having a display side and a non-display side that are disposed on opposite to each other, wherein the display panel has an under screen camera area, the under screen camera area comprises a plurality of pixel areas and a light-transmitting area disposed at a side of the plurality of pixel areas, and the display panel comprises:
a plurality of pixel structures, disposed in the plurality of pixel areas, wherein each of the plurality of pixel structures is disposed in a corresponding one of the plurality of pixel areas, each of the plurality of pixel areas comprises a pixel driving layer, a planarization layer, a pixel defining layer, and a sub-pixel unit that are sequentially stacked on one another, the planarization layer defines a plurality of connecting holes, and the pixel defining layer defines a plurality of pixel openings;
wherein each sub-pixel unit comprises:
a sub-pixel, disposed in a corresponding one of the plurality of pixel openings, wherein an anode of the sub-pixel is electrically connected to the pixel driving layer through a corresponding one of the plurality of connecting holes; and
an isolation structure, protruding from the pixel defining layer and surrounding the corresponding one of the plurality of pixel openings, wherein the isolation structure is electrically connected to a cathode of the sub-pixel surrounded by the isolation structure;
wherein each of the plurality of connecting holes is located within an orthographic projection of the corresponding isolation structure on the planarization layer;
or,
the planarization layer further extends to the light-transmitting area, and the plurality of connecting holes are defined in the light-transmitting area;
or,
the planarization layer further extends to the light-transmitting area, a part of each of the plurality of connecting holes is defined in a corresponding one of the plurality of pixel areas, another part of each of the plurality of connecting holes is defined in the light-transmitting area, and the part of each of the plurality of connecting holes defined in the plurality of pixel areas is located within an orthographic projection of the corresponding isolation structure on the planarization layer; and
a camera module, disposed on the non-display side of the display panel and arranged corresponding to the under screen camera area.

12. The device as claimed in claim 11, wherein the anode is disposed in the corresponding one of the plurality of pixel openings, extends into the corresponding one of the plurality of connecting holes, and covers a sidewall of the corresponding one of the plurality of connecting holes to electrically connect to the pixel driving layer through the corresponding one of the plurality of connecting holes; and
a part of the anode disposed in the corresponding one of the plurality of connecting holes surrounds and defines a conductive groove, and the conductive groove is arranged in a one-to-one correspondence with the plurality of connecting holes.

13. The device as claimed in claim 12, wherein in a direction substantially perpendicular to the pixel driving layer, the isolation structure comprises a conductive portion and a shielding structure sequentially stacked on one another; and
the shielding structure shields the conductive portion and extends beyond the conductive portion in a direction substantially parallel to a plane where the pixel defining layer is located, the conductive portion comprises a metal layer that is opaque, and an orthographic projection of the conductive groove on the pixel driving layer is located within an orthographic projection of the conductive portion on the pixel driving layer.

14. The device as claimed in claim 13, wherein the isolation structure is arranged in an one-to-one correspondence with the sub-pixel, the isolation structure is arranged in an one-to-one correspondence with the plurality of pixel structures, and in a direction substantially parallel to the pixel defining layer, the conductive groove extends in a surrounding direction of the isolation structure; and
a width direction of the conductive groove refers to a wall thickness direction of the isolation structure corresponding to the conductive groove, a width of a groove opening of the conductive groove is a first size, and the first size is less than 4 μm.

15. The device as claimed in claim 14, wherein a length direction of the conductive groove refers to the surrounding direction of the isolation structure; and
in the length direction, an extending length from an end of the groove opening to another end of the groove opening is a second size, and the second size is greater than the first size.

16. The device as claimed in claim 13, wherein in a wall thickness direction of the isolation structure, an edge of the conductive portion and an edge of the corresponding conductive groove that are adjacent to each other are substantially arranged in parallel.

17. The device as claimed in claim 14, wherein in a direction directed from the groove opening of the conductive groove to a bottom wall of the conductive groove, a width of the conductive groove gradually decreases; and
in a length direction of the conductive groove, an edge of the groove opening of the conductive groove extends in a straight line;
or,
in the length direction of the conductive groove, an edge of the groove opening of the conductive groove extends in a curved line.

18. The device as claimed in claim 11, wherein the display panel further comprises an encapsulation layer and a substrate, wherein the substrate is disposed on a side of the pixel driving layer away from the pixel defining layer, and the encapsulation layer is disposed on a side of the pixel structure away from the substrate and at least encapsulates the sub-pixel in each of the plurality of pixel structures;
the substrate comprises at least one of a polyimide film or a glass substrate; and
the encapsulation layer is disposed on the plurality of pixel areas, covers the sub-pixel, and extends to the isolation structure to cover a part of a surface of a side of the isolation structure that is away from the pixel driving layer;
or,
the encapsulation layer is disposed on the plurality of pixel areas, covers both a side of a surface of the sub-pixel unit that is away from the pixel driving layer, and further covers a side surface of the sub-pixel unit;
or,
the encapsulation layer is disposed on the plurality of pixel areas and the light-transmitting area, and the encapsulation layer covers the substrate.

19. The device as claimed in claim 11, wherein the display panel further comprises a first transparent conductive wiring layer and a second transparent conductive wiring layer;
wherein the first transparent conductive wiring layer is disposed between the pixel defining layer and the planarization layer, an end of the first transparent conductive wiring layer laps with the anode, another end of the first transparent conductive wiring layer extends into a corresponding one of the plurality of connecting holes and covers a sidewall of the corresponding one of the plurality of connecting holes, a part of the first transparent conductive wiring layer disposed in the corresponding one of the plurality of connecting holes surrounds and defines a conductive groove, and the conductive groove is arranged in a one-to-one correspondence with the plurality of connecting holes; and
the second transparent conductive wiring layer is disposed between the pixel driving layer and the planarization layer, an end of the second transparent conductive wiring layer laps with an output electrode of the pixel driving layer, and another end of the second transparent conductive wiring layer extends to a bottom of the corresponding one of the plurality of connecting holes to lap with the conductive groove.

20. A display panel, configured in a device with an under screen camera, the display panel having an under screen camera area, the under screen camera area comprising a plurality of pixel areas and a light-transmitting area disposed at a side of the plurality of pixel areas, and the display panel comprising:
a plurality of pixel structures, disposed in the plurality of pixel areas, wherein each of the plurality of pixel structures is disposed in a corresponding one of the plurality of pixel areas, each of the plurality of pixel areas comprises a pixel driving layer, a planarization layer, a pixel defining layer, and a sub-pixel unit that are sequentially stacked on one another, the planarization layer defines a plurality of connecting holes, and the pixel defining layer defines a plurality of pixel openings;
wherein each sub-pixel unit comprises:
a sub-pixel, disposed in a corresponding one of the plurality of pixel openings, wherein an anode of the sub-pixel is electrically connected to the pixel driving layer through a corresponding one of the plurality of connecting holes; and
an isolation structure, protruding from the pixel defining layer and surrounding the corresponding one of the plurality of pixel openings, wherein the isolation structure is electrically connected to a cathode of the sub-pixel surrounded by the isolation structure;
wherein a part of the anode disposed in the corresponding one of the plurality of connecting holes surrounds and defines a conductive groove, and an orthographic projection of the conductive groove on the pixel driving layer is non-overlapped with an orthographic projection of the corresponding one of the plurality of pixel openings on the pixel driving layer.
